(19) United States
(12) Patent Application Publication
(10) Pub. No.: US 2005/0274995 A1
(43) Pub. Date: Dec. 15, 2005

(54) Image sensor and method of forming the same

(75) Inventor: Won-Je Park, Suwon-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/152,452

(22) Filed: Jun. 14, 2005

(30) Foreign Application Priority Data
Jun. 15, 2004 (KR) 2004-44049

(51) Int. Cl. H01L 31/062

(52) U.S. Cl. 257/291

(57) ABSTRACT

An image sensor includes a photodiode formed in a substrate, a buffer oxide layer, a blocking layer, an upper oxide layer, and a transmission supplementary layer. The buffer oxide layer covers the photodiode, and the blocking layer is disposed on the buffer oxide layer to cover the photodiode. The upper oxide layer covers the blocking layer, and the transmission supplementary layer is interposed between the upper oxide layer and the buffer oxide layer to cover the photodiode. The transmission supplementary layer has a refractive index between the refractive index of the blocking layer and at least one reflective index selected from the refractive indexes of the buffer oxide layer and upper oxide layer.

### CROSS-REFERENCE TO RELATED APPLICATION

This application claims priority under 35 U.S.C. § 119 to Korean Patent Application No. 2004-44049, filed on Jun. 15, 2004 in the Korean Intellectual Property Office, the disclosure of which is incorporated by reference herein in its entirety.

### BACKGROUND OF THE INVENTION

1. Field of the Invention

The present invention relates to a semiconductor device and a method of forming the same. More specifically, the present invention is directed to an image sensor and a method forming the same.

2. Description of the Related Art

The image sensor of a semiconductor device converts externally incident light into electrical signals. A pixel of the CMOS image sensor includes a light receiver and a CMOS logic section. The light receiver senses external light, and the CMOS logic section converts signal charges generated from the light receiver by the sensed light into electrical signals (i.e., data).

The light receiver of a typical CMOS image sensor uses a photodiode. If the external light impinges on the photodiode, electron-hole pairs are produced in the photodiode to generate signal charges. The generated signal charges are accumulated in the photodiode. The accumulated signal charges are converted into data by handling in the CMOS logic section.

Various studies have been performed to enhance the dynamic range of the CMOS-type image sensor. The dynamic range of a CMOS-type image sensor may be lowered by many factors such as, for example, dark current generated by the dangling bond of the substrate surface where the photodiode is formed. Further, metallic elements of the metal layer formed on the top surface of the photodiode may penetrate the photodiode through the oxide layer to generate dark current. Thus, the dark current may lower the dynamic range of the image sensor.

Various efforts have been made to reduce dark currents. One of these efforts will now be described in FIG. 1.

Referring to FIG. 1, a device isolation layer 2 is disposed at a predetermined region of a semiconductor substrate 1 to define a diode region. A P-type well is formed in the diode region “a”. An N-type photodiode 3, a region doped with N-type impurities, is formed in the diode region “b”. The N-type photodiode 3 and the P-type well constitute a PN junction. A P-type photodiode 4 is formed at a surface of the diode region on the N-type photodiode 3. One side of the P-type photodiode extends to be electrically connected to the P-type well. A silicon nitride layer 6 covers the diode region. A buffer oxide layer 5 made of silicon oxide is interposed between the silicon nitride layer 6 and the surface of the diode region. An upper oxide layer 7 is disposed on the silicon nitride 6. The upper oxide layer 7 may include interlayer oxide and may be made of silicon oxide.

In the conventional image sensor, the P-type photodiode 4 can suppress the dark current generated by the dangling bond distributed at the interface of the diode region and the buffer oxide layer 5. That is, among electron-hole pairs, electrons are coupled with holes in the P-type photodiode 4 and the holes are emitted at the P-type well to reduce dark current generated by the dangling bond. The silicon nitride layer 6 prevents metallic elements of the overlying metal layer (e.g., a metal layer for forming an interconnection or a metal layer for forming silicide) from penetrating the photodiodes 3 and 4. Thus, the silicon nitride 6 makes it possible to generate dark currents when the metallic elements penetrate the photodiodes 3 and 4.

The conventional image sensor includes a buffer oxide layer 5, a silicon nitride layer 6, and an upper oxide layer 7 which are sequentially stacked on the photodiodes 3 and 4. For this reason, an externally incident light impinges on the photodiodes 3 and 4 through the upper oxide layer 7, the silicon nitride layer 6, and the buffer oxide layer 5. The impinging light may be partly reflected from the interfaces of layers 5, 6, and 7. That is, the impinging light may be lost through layers 5, 6, and 7 due to its reflection. As a result, light finally reaching the photodiodes 3 and 4 may be lost due to the lower photosensitivity of the image sensor, as compared to the incident light.

### SUMMARY OF THE INVENTION

Exemplary embodiments of the present invention are directed to an image sensor for enhancing the transmissivity of the externally incident light and a method of forming the same.

Exemplary embodiments of the present invention are directed to an image sensor for enhancing photosensitivity and a method of forming the same.

In an exemplary embodiment, there is provided an image sensor. The image sensor includes a photodiode, a buffer oxide layer, a blocking layer, an upper oxide layer, and a transmission supplementary layer which are formed in a substrate. The buffer oxide layer covers the photodiode, and the blocking layer is disposed on the buffer oxide layer to cover the photodiode. The upper oxide layer covers the blocking layer. The transmission supplementary layer is interposed between the upper oxide layer and the buffer oxide layer to cover the photodiode. The transmission supplementary layer has a refractive index between a refractive index of the blocking layer and at least one reflective index selected from the reflective indexes of the buffer oxide layer and upper oxide layer.

In some embodiments, the buffer and upper oxide layers are preferably made of silicon oxide and the blocking layer is preferably made of silicon nitride. The transmission supplementary layer is preferably made of an insulator having a higher refractive index than the silicon oxide and a lower refractive index than the silicon nitride. The transmission supplementary layer is preferably made of silicon oxynitride. The photodiode may include an N-type photodiode formed in the substrate and a P-type photodiode formed at a surface of the substrate on the N-type photodiode. The transmission supplementary layer may be interposed between the blocking layer and the upper oxide layer. Alternatively, the transmission supplementary layer may be interposed between the buffer oxide layer and the blocking layer. Alternatively, the transmission supplementary layer may include a first transmission supplementary layer interposed between the buffer oxide layer and the blocking layer and a second transmission supplementary layer interposed between the blocking layer and the upper oxide layer.

In another exemplary embodiment, there is provided a method of forming an image sensor. The method includes forming a photodiode in a substrate and forming a buffer oxide layer to cover the photodiode. A blocking oxide layer is formed on the buffer oxide to cover the photodiode. An upper oxide layer is formed to cover the blocking layer. A transmission supplementary layer is interposed between the upper oxide layer and the buffer oxide layer to cover the photodiode. The transmission supplementary layer has a refractive index between a refractive index of the blocking layer and at least one reflective index selected from the reflective indexes of the buffer oxide layer and the upper oxide layer.

In some embodiments, the buffer oxide layer and upper oxide layer are preferably made of silicon oxide and the blocking layer is preferably made of silicon nitride. The transmission supplementary layer is preferably made of an insulator having a higher refractive index than the silicon oxide and a lower refractive index than the silicon nitride. The transmission supplementary layer may be made of silicon oxynitride. The formation of the photodiode includes forming an N-type photodiode in a predetermined region of the substrate and forming a P-type photodiode at a surface of the substrate on the N-type photodiode. The formation of the transmission supplementary layer and the blocking layer includes forming the blocking layer on the buffer oxide layer and forming the transmission supplementary layer on the blocking layer. Alternatively, the formation of the transmission supplementary layer and the blocking layer includes forming the transmission supplementary layer on the buffer oxide layer and forming the blocking layer on the transmission supplementary layer. Alternatively, the formation of the transmission supplementary layer and the blocking layer includes forming a first transmission supplementary layer on the buffer oxide layer to cover the photodiode, forming a blocking layer on the first transmission supplementary layer, and forming a second transmission supplementary layer on the blocking layer to cover the photodiode. The transmission supplementary layer includes the first and second transmission supplementary layers.

### BRIEF DESCRIPTION OF THE DRAWINGS

FIG. 1 is a plan view of a light receiver of a conventional image sensor;

FIG. 2 is a cross-sectional view of an image sensor according to an embodiment of the present invention;

FIG. 3 and FIG. 4 are cross-sectional views for explaining the method of forming the image sensor shown in FIG. 2;

FIG. 5 is a cross-sectional view of an image sensor according to another embodiment of the present invention;

FIG. 6 and FIG. 7 are cross-sectional views for explaining the method of forming the image sensor shown in FIG. 5;

FIG. 8 is a cross-sectional view of an image sensor according to still another embodiment of the present invention; and

FIG. 9 and FIG. 10 are cross-sectional views for explaining the method of forming the image sensor shown in FIG. 8.

### DETAILED DESCRIPTION OF THE PREFERRED EMBODIMENTS

The present invention will now be described more fully hereinafter with reference to the accompanying drawings, in which preferred embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the height of layers and regions are exaggerated for clarity. It will also be understood that when a layer is referred to as being “on” another layer or substrate, it can be directly on the other layer or substrate, or intervening layers may also be present. Like numbers refer to like elements throughout.

### Embodiment 1

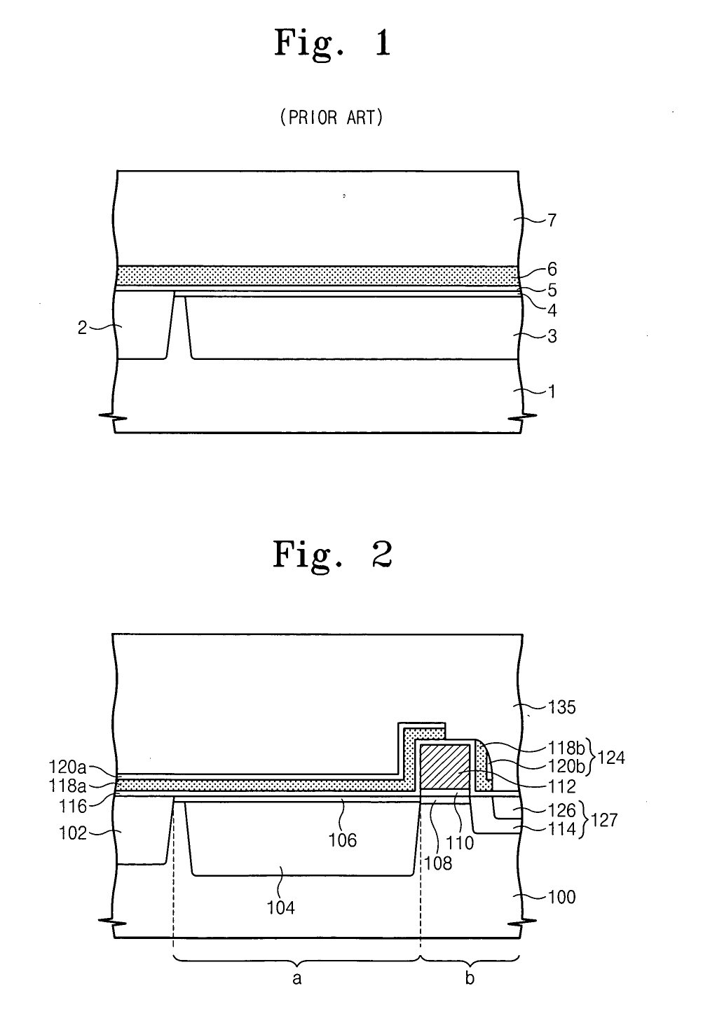

FIG. 2 is a cross-sectional view of an image sensor according to an embodiment of the present invention.

Referring to FIG. 2, a device isolation layer 102 is disposed in a predetermined region of a semiconductor substrate (hereinafter referred to as “substrate”) 100 to define a diode region “a” and a transistor active region “b”. The transistor active region “b” is connected to one side of the diode region “a”. Field effect transistors included in a CMOS logic section of a CMOS-type image sensor may be formed in the transistor active region “b”.

A P-type well is formed in the diode region “a” and the transistor active region “b”. An N-type photodiode 104 is disposed in the diode region “b”. The N-type photodiode 104 and the P-type well constitute a PN junction. A P-type photodiode 106 is disposed at a surface of the diode region “a” on the N-type photodiode 104. One side of the photodiode 106 extends laterally to be electrically connected to the P-type well.

A gate electrode 112 is disposed on the transistor active region “b” adjacent to the diode region “a”. A gate insulation layer 110 is interposed between the gate electrode 112 and a surface of the transistor active region “b”. Although not shown in this figure, other gate electrodes may be sequentially disposed in the transistor active region “b”. The gate electrode 112 may be made of a conductive material (e.g., doped polysilicon or polycide) or a conductive metal containing material. The gate insulation layer 110 may be made of silicon oxide, particularly, thermal oxide. An impurity-doped layer 127 is disposed in respective active regions “b” adjacent to opposite sides of the gate electrode 112. The impurity-doped layer 127 may be doped with P-type impurities. The impurity-doped layer 127 may include a lightly doped layer 114 and a heavily doped layer 126. As illustrated in this figure, the impurity-doped layer 127 may have a double doped drain structure (DDD) structure in which the lightly doped layer 114 surrounds the heavily doped layer 126. Alternatively, the impurity-doped layer 127 may have a lightly doped drain (LDD) structure. The impurity-doped layer 127 may corresponds to a floating diffusion layer of a CMOS-type image sensor, and the gate electrode 112 may correspond to a transfer transistor of a CMOS-type image sensor.

A channel doping layer 108 may be disposed on a surface of the transistor active region “b” below the gate electrode 112. The channel doping layer 108 may be doped with the same impurities as the P-type photodiode 106, i.e., P-type impurities. The channel doping layer 108 may be omitted.

The blocking pattern 118a covers the diode region “a”. That is, the blocking pattern 118a covers the photodiodes 104 and 106. The blocking pattern 118a may laterally extend to partially cover one sidewall and a top surface of the gate electrode 112. A buffer oxide layer 116 may be interposed between the blocking pattern 118a and a surface of the diode region “a”. The buffer oxide layer 116 may laterally extend to cover a sidewall and a top surface of the gate electrode 112 and the surface of the transistor active region “b”.

The blocking pattern 118a may be made of an insulator to prevent penetration of metallic elements. For example, the blocking pattern 118a is preferably made of silicon nitride. The buffer oxide layer 116 is made of a material to reduce a tensile stress between the blocking pattern 118a and the surface of the diode region “a”. For example, the buffer oxide layer 116 is preferably made of silicon oxide. Due to the buffer oxide layer 116, the tensile stress between the blocking pattern 118a and the surface of the diode region “a” is reduced to prevent damage on the surface of the diode region “a”.

An upper oxide layer 135 is disposed to cover the blocking pattern 118a. The upper oxide layer 135 may cover an entire surface of the substrate 100. The upper oxide layer 135 is preferably made of silicon oxide. The upper oxide layer 135 may include at least one interlayer oxide. The upper oxide layer 135 may include oxide having a different function, i.e., prevent a silicidation.

The transmission supplementary pattern 120a is interposed between the blocking pattern 118a and the upper oxide layer 135. Preferably, the transmission supplementary pattern 120a has a sidewall aligned to a sidewall of the blocking pattern 118a. The transmission supplementary pattern 120a covers the photodiodes 104 and 106. Preferably, the bottom surface of the transmission supplementary pattern 120a is in direct contact with the blocking pattern 118a and the top surface of the transmission supplementary pattern 120a is in direct contact with a bottom surface of the upper oxide layer 135.

The transmission supplementary pattern 120a is made of an insulator having a refractive index between a refractive index of the blocking pattern 118a and a refractive index of the upper oxide layer 135. Particularly, if the blocking pattern 118 is made of silicon nitride and the upper oxide layer 135 is made of silicon oxide, the transmission supplementary pattern 120a is preferably made of an insulator having a refractive index higher than silicon oxide and lower than silicon nitride. Preferably, the transmission supplementary pattern 120a is made of, for example, silicon oxynitride.

A gate spacer 124 is disposed on one sidewall of the gate electrode 112 adjacent to the impurity-doped layer 127. Preferably, the spacer 124 includes a first spacer 118a and a second spacer 120b which are stacked in the order named. The first spacer 118b is preferably made of the same material as the blocking pattern 118a, and the second spacer 120b is preferably made of the same material as the transmission supplementary pattern 120a.

In the above-described image sensor, the refractive index of the transmission supplementary pattern 120a ranges from the refractive index of the upper oxide layer 135 to the refractive index of the blocking pattern 118a. That is, a difference between the refractive indexes of the upper oxide layer 135 and the blocking pattern 118a is reduced by the transmission supplementary pattern 120a to enhance a transmissivity of an external light passing the layers 116, 118a, 120a, and 135 stacked on the photodiodes 104 and 106. In other words, a loss of the external light is minimized by the layers 116, 118a, 120a, and 135 to enhance a photosensitivity of the image sensor.

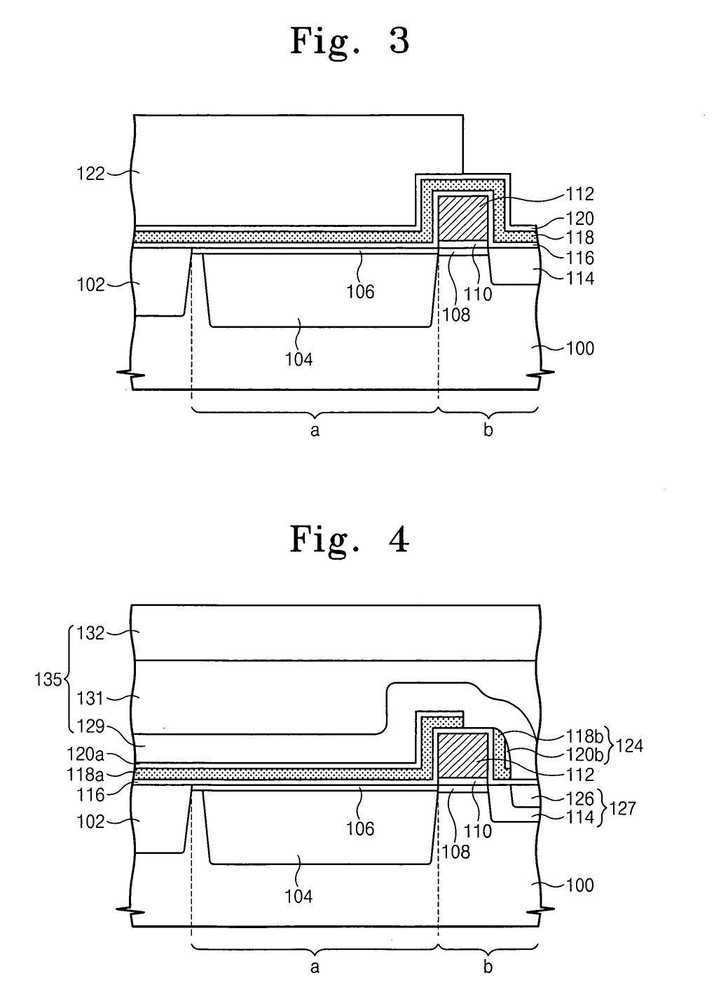

A method of forming the image sensor shown in FIG. 2 will now be described with reference to FIG. 3 and FIG. 4.

Referring to FIG. 3, a device isolation layer 102 is formed in a predetermined region of a substrate 100 to define a diode region “a” and a transistor active region “b”. The transistor active region “b” is connected to one side of the diode region “a”. A P-type well is formed in the diode region “a” and the transistor active region “b”. The formation of the P-type well may be performed using impurity implantation. The P-type well may be formed after or before formation of the device isolation layer 102.

Impurities are selectively implanted to form an N-type photodiode 104 in the diode region “a”. Impurities are selectively implanted into a surface of the diode region “a” on the N-type photodiode 104 to form the P-type photodiode 106.

Preferably, one side of the photodiode 106 is electrically connected to the P-type well.

The channel doping layer 108 may be formed on a surface of the transistor active region “b” adjacent to the diode region “a”. The formation of the channel doping layer 108 may be performed by implanting P-type impurities. In some cases, the P-type photodiode 106 and the channel doping layer 108 may be formed at the same time.

The gate insulation layer 110 and the gate conductive layer are sequentially formed on an entire surface of the substrate 100. The gate conductive layer is patterned to form a gate electrode 112 covering the channel doping layer 108. The gate insulation layer is interposed between the gate electrode 112 and the transistor active region “b”. The gate insulation layer 110 may be made of silicon oxide, particularly, thermal oxide. The gate electrode 112 may be made of a conductive material (e.g., doped polysilicon or polycide) or a conductive metal containing material.

Impurities are selectively implanted to form a lightly doped layer 114 in the transistor active region disposed at opposite sides adjacent to the photodiodes 104 and 106. The lightly doped layer 114 may be doped with P-type impurities.

The gate insulation layer 110 formed at the diode region “b” disposed at opposite sides adjacent to the gate electrode and on the surface of the transistor active region “b” may be removed using a wet etch after formation of the lightly doped layer 114.

The buffer oxide layer 116 is formed on an entire surface of a substrate 100 including the lightly doped layer 114. Preferably, the buffer oxide layer 116 is made of silicon oxide. The buffer oxide layer 116 may be made of thermal oxide or silicon oxide based on chemical vapor deposition (CVD). The blocking layer 116 and the transmission supplementary layer 120 are sequentially formed on the buffer oxide layer 116. They are conformally formed. Preferably, the blocking layer 118 is made of an insulator to prevent penetration of metallic elements, for example, silicon nitride.

The photoresist pattern 122 is formed on the transmission supplementary layer 120 to cover the diode region “a”. Thus, the transmission supplementary layer 120 formed on the transistor active region “b” is exposed. The photoresist pattern 122 may laterally extend to cover one sidewall and a top surface of the gate electrode 112 adjacent to the diode region “a”.

Referring to FIG. 4, using the photoresist pattern 122 as an etch mask, the transmission supplementary layer 120 and the blocking layer 118 are successively anisotropically etched to form the blocking pattern 118a and the transmission supplementary pattern 120a which are sequentially stacked on the diode region “a” and to form the gate spacer 124 on one sidewall of the gate electrode 112. In this case, the buffer oxide layer 116 may act as an etch-stop layer. The gate spacer 124 includes a first spacer 118b and the second spacer 120b which are stacked in the order named. The transmission supplementary pattern 120a is made of the same material as the second spacer 120b, and the blocking pattern 118a is made of the same material as the first spacer 120b.

Following formation of the gate spacer 124, the photoresist pattern 122 is removed.

Using the gate spacer 124 as a mask, impurities are selectively implanted to form the heavily doped layer 126. The lightly and heavily doped layers 114 and 126 constitute the impurity-doped layer 127. The impurity-doped layer 127 is formed in the transistor active region “b” disposed at opposite sides adjacent to the photodiodes 104 and 106. The impurity-doped layer 127 may correspond to a floating diffusion layer of a CMOS-type image sensor. The impurity-doped layer 127 may have an LDD or DDD structure.

The upper oxide layer 135 is formed to cover the transmission supplementary pattern 120a. Preferably, the upper oxide layer 135 is made of silicon oxide. The transmission supplementary pattern 120a is made of an insulator having a refractive index between a refractive index of the upper oxide layer 135 and a refractive index of the blocking pattern 118a. Particularly, if the upper oxide layer 135 is made of silicon oxide and blocking pattern 118a is made of silicon nitride, the transmission supplementary pattern 120a is preferably made of an insulator having a refractive index higher than the silicon oxide and lower than the silicon nitride. Preferably, the transmission supplementary pattern 120a is made of, for example, silicon oxynitride.

The upper oxide layer 135 may include the silicide barrier layer 129, which is made of silicon oxide. The silicide barrier layer 129 covers the transmission supplementary pattern 120a, and may cover the gate electrode 112 and the impurity-doped layer 127. The silicide barrier layer 129 may prevent metal silicide form being formed on a surface of the impurity-doped layer 127. The upper oxide layer 135 may include at least one interlayer oxide layer formed on the silicide barrier layer 129. In FIG. 4, there are shown first and second interlayer oxide layers 131 and 132. They are made of silicon oxide.

Although not shown in this figure, a passivation layer may be formed on the upper oxide layer 135.

In the above-described method, while the blocking pattern 118a and the transmission supplementary pattern 120a are formed, the photodiodes 104 and 106 are not exposed to plasma used in an etch process. Thus, the photodiodes 104 and 106 may be protected from plasma damage to prevent degradation of the photodiodes 104 and 106.

The transmission supplementary pattern 120a is formed between the blocking pattern 118a and the upper oxide layer 135 to reduce the difference between refractive indexes of the upper blocking oxide layer 135 and the blocking pattern 118a. Thus, a transmission coefficient of an externally incident light increases to enhance a photosensitivity of the image sensor.

### Embodiment 2

In another embodiment, a modified version of the transmission supplementary layer according to the first embodiment will now be described. Therefore, same numerals denote same elements throughout the first and second embodiments.

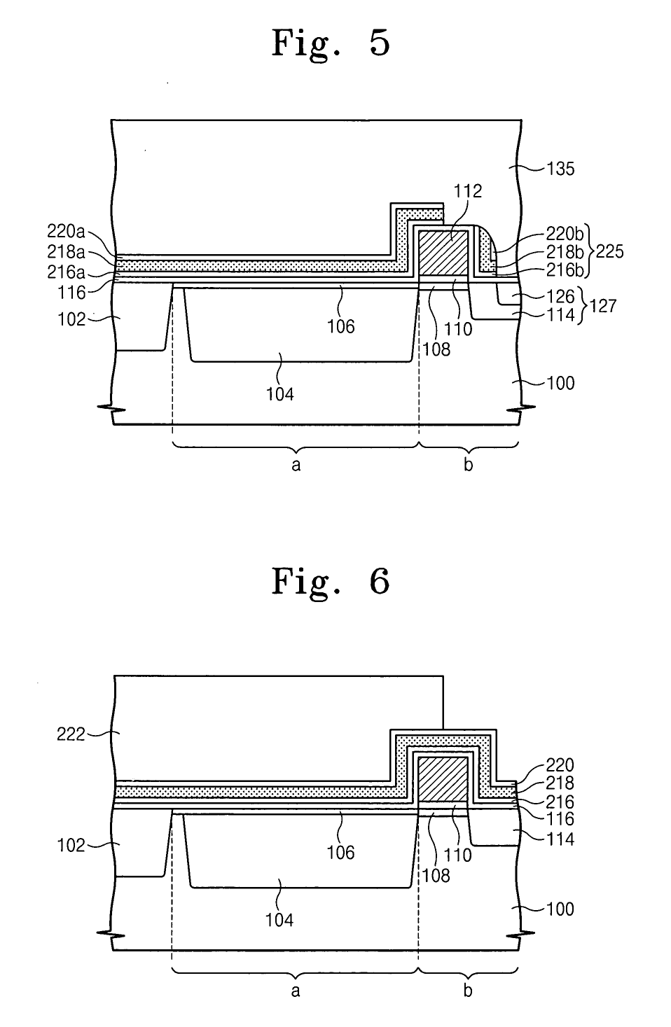

FIG. 5 is a cross-sectional view of an image sensor according to another embodiment of the present invention.

Referring to FIG. 5, a device isolation layer 102 is disposed in a substrate 100 to define the diode region “a” and the transistor active region “b”. The transistor active region “b” is connected to the diode region “a”. The P-type well may be disposed in the diode region “a” and the transistor active region “b”. As previously stated in the first embodiment, N- and P-type photodiodes 104 and 106 are disposed in the diode region “a” and the gate electrode 112 is disposed over the transistor active region “b” with the gate insulation layer 110 interposed therebetween. The channel doping layer 108 may be disposed on the surface of the transistor active region “b” below the gate electrode 112.

Blocking pattern 218a is disposed to cover the diode region “a”. The blocking pattern 218a covers the photodiodes 104 and 106. Preferably, the blocking pattern 218a is made of an insulator to prevent penetration of metallic elements. Therefore, the blocking pattern 218a is preferably made of, for example, silicon nitride. The blocking pattern 218a may laterally extend to partially cover one sidewall and a top surface of the adjacent gate electrode 112. The buffer oxide layer 116 is interposed between the blocking pattern 218a and a surface of the diode region “a”. Preferably, the buffer oxide layer 116 is made of silicon oxide. The buffer oxide layer 116 may laterally extend to cover a surface of the gate electrode and a surface of the active region “b”. The upper oxide layer 135 covers the blocking pattern 218a. Preferably, the upper oxide layer 135 is made of silicon oxide. As previously described in the first embodiment, the upper oxide layer 135 may include at least one interlayer oxide or oxide of another function.

The first transmission supplementary pattern 216a is interposed between the blocking pattern 218a and the buffer oxide layer 116, and the second transmission supplementary pattern 220a is interposed between the blocking pattern 218a and the upper oxide layer 135. The first transmission supplementary pattern 216a is made of an insulator having a refractive index between a refractive index of the buffer oxide layer 116 and a refractive index of the blocking pattern 218a. The second transmission supplementary pattern 220a is made of an insulator having a refractive index between a refractive index of the upper oxide layer 135 and a refractive index of the blocking pattern 218a. The bottom and top surfaces of the first transmission supplementary pattern 216a are preferably in direct contact with the top surface of the blocking pattern 218a and the bottom surface of the upper oxide layer 135, respectively. The first transmission supplementary pattern 216a, the blocking pattern 218a, and the second transmission supplementary pattern 220a have sidewalls aligned to one another.

If the buffer oxide layer 116 and the upper oxide layer 135 are made of silicon oxide and the blocking pattern 218a is made of silicon nitride, the first and second transmission supplementary patterns 216a and 220a are made of an insulator having a higher refractive index than the silicon oxide and a lower refractive index than the silicon nitride. Preferably, the first and second transmission supplementary patterns 216a and 220a are made of, for example, silicon oxynitride.

Gate spacer 225 is disposed on one sidewall of the gate electrode 112 opposite to the diode region “a”. The gate spacer 225 includes first, second, and third spacers 216b, 218b, and 220b which are stacked in the order named. The first spacer 216b and the first transmission supplementary pattern 216a are made of the same material, and the third spacer 220b and the second transmission supplementary pattern 220a are made of the same material.

As previously described in the first embodiment, an impurity-doped layer 127 is disposed in the transistor active region “b” adjacent to one side of the gate electrode 112 opposite to the diode region “a”. The impurity-doped layer 127 may include lightly and heavily doped layers 114 and 126 to have an LDD or DDD structure.

In the above-described image sensor, a first transmission supplementary pattern 216a is interposed between the buffer oxide layer 116 and the blocking pattern 218a to reduce the difference between the refractive index of the buffer oxide layer 116 and the refractive index of the blocking pattern 218a. The second transmission supplementary pattern 220a is interposed between the blocking pattern 218a and the upper oxide layer 135 to reduce the difference between the refractive index of the blocking pattern 218a and the refractive index of the upper oxide layer 135. Accordingly, the transmission coefficient of the external light passing the layers 116, 216a, 218a, 220a, and 135 on the photodiodes 104 and 106 increases. As a result, the loss of the light impinging on the photodiodes 104 and 106 is reduced to enhance the photosensitivity of the image sensor.

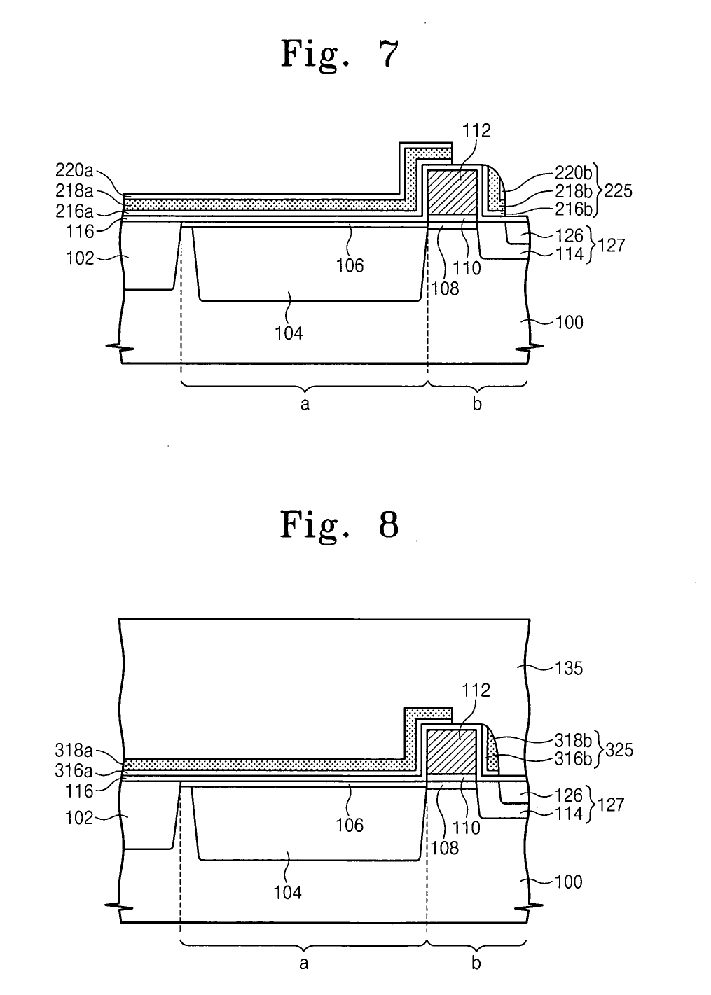

FIG. 6 and FIG. 7 are cross-sectional views for showing a method of forming the image sensor shown in FIG. 5.

Referring to FIG. 6, device isolation layer 102, photodiodes 104 and 106, channel doping layer 108, gate electrode 112, lightly doped layer 114, and buffer oxide layer 116 are formed using the same manner as described in the first embodiment.

The first transmission supplementary layer 216, the blocking layer 218, and the second transmission supplementary layer 220 are sequentially formed on a substrate 100 including the buffer oxide layer 116. Preferably, the layers 216, 218, and 220 are conformally formed.

A photoresist pattern 222 is formed on the second transmission supplementary layer 220 to cover a diode region “a”. In this case, the second transmission supplementary layer 220 over the transistor active region “b” is exposed. The photoresist pattern 220 may laterally extend to partially cover one sidewall and the top surface of the gate electrode 112 adjacent to the diode region “a”.

Referring to FIG. 7, using the photoresist pattern 222 as an etch mask, the second transmission supplementary layer 220, the blocking layer 218, and the first transmission supplementary layer 216 are successively anisotropically etched to form the first transmission supplementary pattern 216a, the blocking pattern 218a, and the second transmission supplementary pattern 220a which are sequentially stacked on the diode region “a” and to form the gate spacer 225 on one sidewall of the gate electrode 112. The gate spacer 225 includes first, second, and third spacers 216b, 218b, and 220b, which are stacked in the order named. The first, second, and third spacers 216b, 218b, and 220b are made of the same material as the first transmission supplementary pattern 216a, the blocking pattern 218a, and the second transmission supplementary pattern 220a, respectively.

Following formation of the patterns 216a, 218a, and 220a and the spacer 225, the photoresist pattern 222 is removed.

An upper oxide layer 135 shown in FIG. 5 is formed. Preferably, the upper oxide layer 135 is made of silicon oxide. As previously described in the first embodiment, the upper oxide layer 135 may include a silicide barrier layer made of silicon oxide and/or at least one interlayer oxide layer.

In the above-described method, the photodiodes 104 and 106 are not exposed to plasma of an etch process during formation of the patterns 216a, 218a, and 220a on the photodiodes 104 and 106. Thus, the photodiodes 104 and 106 may be protected from plasma damage to prevent their degradation.

The first transmission supplementary pattern 216a reduces the difference between a refractive index of the blocking pattern 218a and a refractive index of the buffer oxide layer, and the second transmission supplementary pattern 220a reduces the difference between the refractive index of the blocking pattern 218a and the refractive index of the upper oxide layer 135. Accordingly, the loss of the externally incident light is reduced to enhance a photosensitivity of the image sensor.

### Embodiment 3

In yet another embodiment, a modified version of the transmission supplementary layer according to the first embodiment will now be described. Therefore, same numerals denote the same elements throughout the first and third embodiments.

FIG. 8 is a cross-sectional view of an image sensor according to another embodiment of the present invention.

Referring to FIG. 8, blocking pattern 318a is disposed on the buffer oxide layer 116 to cover a diode region “a”. Upper oxide layer 135 is disposed on the blocking pattern 318a to cover the diode region “a”. The blocking pattern 318a is made of an insulator to prevent penetration of metallic elements. Preferably, the blocking pattern 318a is made of, for example, silicon nitride. As previously described in the first and second embodiments, the buffer oxide layer 116 and the upper oxide layer 135 are preferably made of silicon oxide.

Transmission supplementary layer 316a is disposed between the blocking pattern 318a and the buffer oxide layer 116. Bottom and top surfaces of the penetration supplementary pattern 316a are preferably in direct contact with the top surface of the buffer oxide layer 116 and the bottom surface of the blocking pattern 318a, respectively.

The transmission supplementary pattern 316a is made of an insulator having a refractive index between the refractive index of the buffer oxide 116 and the refractive index of the blocking pattern 318a. Particularly, if the blocking pattern 318a is made of silicon nitride and the upper oxide layer 116 is made of silicon oxide, the transmission supplementary pattern 316a is preferably made of an insulator having a refractive index higher than the silicon oxide and lower than the silicon nitride. Preferably, the transmission supplementary pattern 316a is made of, for example, silicon oxynitride.

A gate spacer 325 is disposed on one sidewall of the gate electrode 112 opposite to the diode region “a”. The spacer 325 includes a first spacer 316b and a second spacer 318b which are stacked in the order named. The first spacer 316b is made of the same material as the transmission supplementary pattern 316a, and the second spacer 318b is made of the same material as the blocking pattern 318a.

In the above-described image sensor, the transmission supplementary pattern 316a is disposed between the buffer oxide layer 116 and the blocking pattern 318a to reduce a difference between a refractive index of the buffer oxide layer 116 and a refractive index of the blocking pattern 318a. Accordingly, an absorption coefficient of the external light increases to enhance the photosensitivity of the image sensor.

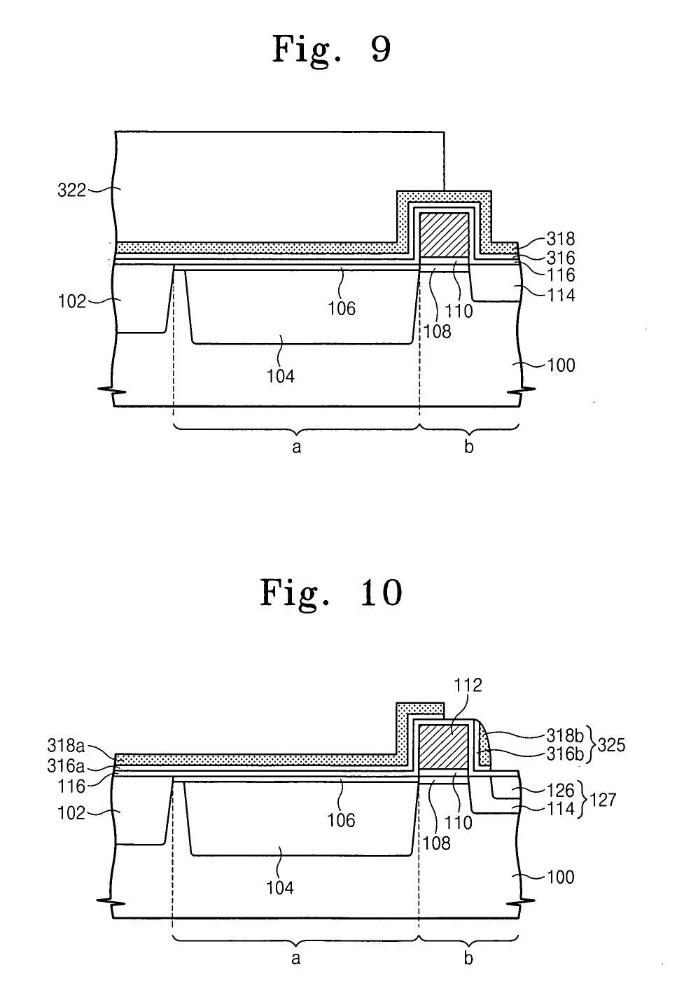

FIG. 9 and FIG. 10 are cross-sectional views showing a method of forming the image sensor shown in FIG. 8.

Referring to FIG. 9, from formation of the device isolation layer to formation of the buffer oxide layer 116, the third embodiment is substantially identical to the first and second embodiments.

The transmission supplementary layer 316 and the blocking layer 318 are conformally formed on the buffer oxide layer 116. The transmission supplementary layer 316 is made of an insulator having a refractive index between the refractive index of the buffer oxide layer 116 and the refractive index of the blocking layer 318. Particularly, if the buffer oxide layer 116 is made of silicon oxide and the blocking layer 318 is made of silicon nitride, the transmission supplementary layer 316 is made of an insulator having a refractive index higher than the silicon oxide and lower than the silicon nitride. Preferably, the transmission supplementary layer 316 is made of, for example, silicon oxynitride.

A photoresist pattern 322 is formed on the blocking layer 318 to cover photodiodes 104 and 106 formed in the diode region “a”. In this case, the blocking layer 318 over the transistor active region “b” is exposed. The photoresist pattern 318 may laterally extend to partially cover one sidewall and the top surface of the gate electrode adjacent to the photodiodes 104 and 106.

Referring to FIG. 10, using the photoresist pattern 322 as an etch mask, the blocking layer 318 and the transmission supplementary layer 316 are successively anisotropically etched to form the transmission supplementary pattern 316a and the blocking pattern 318a which are sequentially stacked on the photodiodes 104 and 106 and to form a gate spacer 325 on one sidewall of the gate electrode 112. In this case, the buffer oxide layer 116 may act as an etch-stop layer. The gate spacer 325 includes a first spacer 316b and a second spacer 318b which are stacked in the order named. The first spacer 316b is made of the same material as the transmission supplementary pattern 316a, and the second spacer 318b is made of the same material as the blocking pattern 318a.

The photoresist pattern 322 is removed from the substrate 100.

The upper oxide layer 135 shown in FIG. 8 is formed. As previously described in the first and second embodiments, the upper oxide layer 135 may include a silicide barrier layer made of silicon oxide and/or at least one interlayer oxide layer.

In the above-described method, the photodiodes 104 and 106 are not exposed to plasma during an etch process for forming the transmission supplementary pattern 316a and the blocking pattern 318a. Therefore, it is possible to prevent degradation of the photodiodes 104 and 106. Since the transmission supplementary pattern 316 is disposed between the buffer oxide layer 116 and the blocking pattern 318a, the difference between the refractive index of the buffer oxide layer 116 and the refractive index of the transmission supplementary pattern 316 may be reduced to enhance a photosensitivity of the image sensor.

The image sensor according to the present invention is not limited to CMOS-type image sensors. That is, the teachings of the present invention may be applied to all images sensors using at least one of the photodiodes 104 and 106.

As explained so far, the transmission supplementary pattern interposes between the blocking pattern covering the photodiode and the upper oxide layer and/or between the blocking pattern and the buffer oxide layer. The transmission supplementary pattern reduces the difference between the refractive index of the blocking pattern and the refractive of the upper oxide layer and/or the difference between the refractive index of the blocking pattern and the refractive index of the buffer oxide layer. Thus, increasing the absorption coefficient of the light will enhance the photosensitivity of the image sensor.

Although the present invention has been described with reference to the preferred embodiments thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

1. An image sensor comprising:
a photodiode formed on a substrate;
a buffer oxide layer covering the photodiode;
a blocking layer disposed on the buffer oxide layer to cover the photodiode;
an upper oxide layer covering the blocking layer; and
a transmission supplementary layer interposed between the upper oxide layer and the buffer oxide layer to cover the photodiode, the transmission supplementary layer having a refractive index between the refractive index of the blocking layer and at least one reflective index selected from the reflective indexes of the buffer oxide layer and upper oxide layer.

2. The image sensor as recited in claim 1, wherein the buffer oxide layer and upper oxide layer are made of silicon oxide and the blocking layer is made of silicon nitride, and the transmission supplementary layer is made of an insulator having a refractive index higher than the silicon oxide and lower than the silicon nitride.

3. The image sensor as recited in claim 2, wherein the transmission supplementary layer is made of silicon oxynitride.

4. The image sensor as recited in claim 1, wherein the photodiode comprises:
an N-type photodiode formed in the substrate; and
a P-type photodiode formed at a surface of the substrate on the N-type photodiode.

5. The image sensor as recited in claim 1, wherein the transmission supplementary layer is interposed between the blocking layer and the upper oxide layer.

6. The image sensor as recited in claim 1, wherein the transmission supplementary layer is interposed between the buffer oxide layer and the blocking layer.

7. The image sensor as recited in claim 1, wherein the transmission supplementary layer comprises:
a first transmission supplementary layer interposed between the buffer oxide layer and the blocking layer; and
a second transmission supplementary layer interposed between the blocking layer and the upper oxide layer.

8. A method of forming an image sensor comprising:
forming a photodiode on a substrate;
forming a buffer oxide layer to cover the photodiode;
forming a blocking layer on the buffer oxide layer to cover the photodiode;
forming an upper oxide layer to cover the blocking layer; and
forming a transmission supplementary layer between the upper oxide layer and the buffer oxide layer to cover the photodiode, the transmission supplementary layer having a refractive index between the refractive index of the blocking layer and at least one reflective index selected from the reflective indexes of the buffer oxide layer and upper oxide layer.

9. The method as recited in claim 8, wherein the buffer and upper oxide layers are made of silicon oxide and the blocking layer is made of silicon nitride, and the transmission supplementary layer is made of an insulator having a refractive index higher than the silicon oxide and lower than the silicon nitride.

10. The method as recited in claim 9, wherein the transmission supplementary layer is made of silicon oxynitride.

11. The method as recited in claim 8, wherein the formation of the photodiode comprises:
forming an N-type photodiode in a predetermined region of the substrate; and
forming a P-type photodiode at a surface of the substrate on the N-type photodiode.

12. The method as recited in claim 8, wherein the formation of the transmission supplementary layer and the blocking layer comprises:
forming the blocking layer on the buffer oxide layer; and
forming the transmission supplementary layer on the blocking layer.

13. The method as recited in claim 8, wherein the formation of the transmission supplementary layer and the blocking layer comprises:
forming the transmission supplementary layer on the buffer oxide layer; and
forming the blocking layer on the transmission supplementary layer.

14. The method as recited in claim 8, wherein the formation of the transmission supplementary layer and the blocking layer comprises:
forming a first transmission supplementary layer on the buffer oxide layer to cover the photodiode;
forming the blocking layer on the first transmission supplementary layer; and
forming a second transmission supplementary layer on the blocking layer to cover the photodiode,
wherein the transmission supplementary layer comprises the first and second transmission supplementary layers.

15. An image sensor comprising:
a photodiode formed on a substrate;
a buffer oxide layer covering the photodiode;
a blocking layer disposed on the buffer oxide layer to cover the photodiode;
an upper oxide layer covering the blocking layer; and
a transmission supplementary layer interposed between the blocking layer and the buffer oxide layer to cover the photodiode, the transmission supplementary layer having a refractive index between the refractive index of the blocking layer and at least one reflective index selected from the reflective indexes of the buffer oxide layer and upper oxide layer.

16. The image sensor as recited in claim 15, wherein the buffer oxide layer and upper oxide layer are made of silicon oxide and the blocking layer is made of silicon nitride, and the transmission supplementary layer is made of an insulator having a refractive index higher than the silicon oxide and lower than the silicon nitride.

17. The image sensor as recited in claim 16, wherein the transmission supplementary layer is made of silicon oxynitride.

18. The image sensor as recited in claim 15, wherein the photodiode comprises:
an N-type photodiode formed in the substrate; and
a P-type photodiode formed at a surface of the substrate on the N-type photodiode.
